(19) United States
(12) Patent Application Publication
(10) Pub. No.: US 2025/0237960 A1
(43) Pub. Date: Jul. 24, 2025

(54) METHODS, COMPUTER PROGRAMS AND APPARATUSES FOR TREATING AN OPTICAL ELEMENT FOR THE EXTREME ULTRAVIOLET WAVELENGTH RANGE

(71) Applicant: Carl Zeiss SMS Ltd., D.N. Misgav (IL)

(72) Inventors: Sergey Oshemkov, Akko (IL); Alexander Gusarov, Beer Ora (IL); Vladimir Dmitriev, Tsurit (IL); Avi Cohen, Haifa (IL); Thomas Scheruebl, Jena (DE)

(21) Appl. No.: 19/032,895

(22) Filed: Jan. 21, 2025

(30) Foreign Application Priority Data
Jan. 22, 2024 (EP) 24153219.1

(51) Int. Cl. G03F 7/00; G03F 1/76; G03F 7/20

(52) U.S. Cl. CPC G03F 7/70041; G03F 1/76; G03F 7/2022; G03F 7/70025; G03F 7/70316; G03F 7/70525; G03F 7/7055

(57) ABSTRACT

A method for treating an optical element for the extreme ultraviolet (EUV) wavelength range, the method comprises providing a pulsed laser irradiation, wherein the pulsed laser irradiation comprises a plurality of pulse sequences, each pulse sequence comprising a plurality of pulses, wherein a first pulse and a second pulse of the plurality of pulses are separated by a time of 100 ns or less, and directing the laser irradiation onto the optical element for the EUV wavelength range.

### CROSS-REFERENCE TO RELATED APPLICATIONS

This application claims priority to European Application EP 24153219.1, filed on Jan. 22, 2024, the entire content of which is incorporated herein by reference.

### TECHNICAL FIELD

The present invention relates to methods, computer programs and apparatuses for treating an optical element for the extreme ultraviolet (EUV) wavelength range.

### BACKGROUND

With ever-decreasing dimensions of feature sizes, e.g., on silicon wafers, corresponding lithographic masks, etc., extremely short wavelengths are required to reach the intended level of resolution. For example, EUV lithography (e.g., at a wavelength of 13.5 nm) plays an important role in providing such small features. While the short wavelength allows for an increased resolution, essential for the manufacturing requirements, on the one hand, it also introduces critical complications on the other hand: For example, the reflectance of single metallic surfaces is negligible for these wavelengths, which is why conventional mirrors (e.g., silver (Ag) or gold (Au) mirrors) are not applicable in such applications.

Optical elements, e.g., comprising multilayer systems of alternating Mo/Si layers, however, are suitable as EUV mirrors (e.g., wavelengths of and around 13.5 nm). These multilayer systems typically comprise a periodic alternating arrangement of two materials with a significantly different index of refraction (e.g., molybdenum (Mo) and silicon (Si)). This corresponds to a Bragg mirror, in which constructive interference may be achieved for a certain angle of incidence and a required wavelength range (e.g., in the EUV). Mo/Si multilayers with additional diffusion barriers at selected interfaces have demonstrated a reflectance of 70% or more. The layer thickness required for high near-normal incidence reflectance at 13.5 nm wavelength is in the nanometer range to achieve constructive interference with ca. 50 multilayer periods.

In reality, such multilayer systems are no perfect reflectors. E.g., their interfaces are not chemically abrupt which may result in a diminished optical contrast and consequently to lower reflectance at the respective interface. Imperfections at the (e.g., Mo/Si) interfaces (e.g., resulting from interdiffusion, compound formation, and/or roughness) and unavoidable absorption are the main reasons for said losses.

In general, present methods for treating and/or modifying such optical elements, e.g., comprising multilayer systems, still yield various challenges: For example, some methods rely on illuminating the multilayer systems from the backside (i.e., the side with no absorber material) in order to prevent substantial influence of the absorber pattern load/density on the illumination intensity passing the absorber layer (as observed in frontside illumination). The same treatment of layers closer to pattern, e.g., by frontside illumination, may result in higher reflectivity suppression on the one hand, but on the other hand, it yields disadvantages compared to backside illumination: E.g., backside processing may, e.g., be selected due to its immunity to the pattern load. In detail, an incoming illumination in an area of the multilayer system with a densely packed absorber pattern may be attenuated strongly while in less densely packed areas, it may be attenuated less. Thereby, the effective illumination intensity for multilayer system treatment may vary depending on the position of the multilayer system which may make the process less reproducible, accurate, and/or controllable.

However, in backside illumination, the modification of the optical element requires high intensities and may be accompanied with high intensity-related unwanted side effects: E.g., this process typically suffers from the high induced multilayer system compaction and a relatively bigger registration impact. Further, the high multilayer opacity treatment affects mostly layers close to the back surface.

WO 2022/201138 A1 relates to a method for generating at least one local surface modification of a material of an optical element used in a lithographic system. The method comprises the steps: (a) focusing a first energy pulse in the optical element; and (b) sequentially focusing at least one second energy pulse within a time interval which is shorter than a cooling time of the material, the at least one second energy pulse at least partially locally overlapping the first energy pulse so that the surface of the optical element is locally modified.

US 2020/159111 A1 relates to a method for compensating at least one defect of a mask blank. The method includes the following steps: (a) obtaining data in respect of a position of the at least one defect of the mask blank; (b) obtaining design data for pattern elements which should be produced on the mask blank; (c) determining whether the at least one defect is arranged relative to a pattern element to be produced in such a way that it has substantially no effect when exposing a wafer using the mask blank that is provided with the pattern element to be produced; and (d) otherwise, displacing the at least one defect on the mask blank in such a way that it has substantially no effect when exposing the wafer using the mask blank that is provided with the pattern element to be produced.

US 2018/221988 A1 relates to a method for laser processing a transparent workpiece including forming a contour line having defects in the transparent workpiece. The method includes directing a pulsed laser beam oriented along a beam pathway through a beam converting element and through a phase modifying optical element such that the portion of the pulsed laser beam directed into the transparent workpiece includes a phase shifted focal line having a cross-sectional phase contour that includes phase contour ridges induced by the phase modifying optical element and extending along phase ridge lines. Moreover, the phase shifted focal line generates an induced absorption within the transparent workpiece to produce a defect within the transparent workpiece including a central defect region and a radial arm that extends outward from the central defect region in a radial defect direction oriented within 20° of the phase ridge lines of the phase shifted focal line.

US 2021/379695 A1 relates to a method of laser processing a transparent workpiece including directing a pulsed laser beam into the transparent workpiece. The pulsed laser beam includes pulse bursts having 2 sub-pulses per pulse burst or more, each pulse burst of the pulsed laser beam has a burst duration Tbd of 380 ns or greater; and the pulsed laser beam forms a pulsed laser beam focal line in the transparent workpiece, the pulsed laser beam focal line inducing absorption in the transparent workpiece, the induced absorption producing a defect in the transparent workpiece. The pulsed laser beam focal line includes a wavelength λ, a spot size wo, and a Rayleigh range ZR that is greater than FDTTWO2λ, where FD is a dimensionless divergence factor comprising a value of 10 or greater.

US 2013/126573 A1 relates to a method for the internal processing of a transparent substrate in preparation for a cleaving step. The substrate is irradiated with a focused laser beam that is comprised of pulses having an energy and pulse duration selected to produce a filament within the substrate. The substrate is translated relative to the laser beam to irradiate the substrate and produce an additional filament at one or more additional locations. The resulting filaments form an array defining an internally scribed path for cleaving said substrate. Laser beam parameters may be varied to adjust the filament length and position, and to optionally introduce V-channels or grooves, rendering bevels to the laser-cleaved edges. Preferably, the laser pulses are delivered in a burst train for lowering the energy threshold for filament formation, increasing the filament length, thermally annealing of the filament modification zone to minimize collateral damage, improving process reproducibility, and increasing the processing speed compared with the use of low repetition rate lasers.

Therefore, there is still a need to improve methods, computer programs and apparatuses for treating an optical element for the EUV wavelength range, such as to improve reflectivity suppression and/or a compaction.

### SUMMARY

The invention solves the above problems at least in part.

A first aspect of the present invention relates to a method for treating an optical element for the EUV wavelength range. The method comprises providing a pulsed laser irradiation (herein also referred to as “laser irradiation”), wherein the pulsed laser irradiation comprises a plurality of pulse sequences, each pulse sequence comprising a plurality of pulses, wherein a first pulse and a second pulse of the plurality of pulses are separated by a time of 100 ns or less, preferably 10 ns or less, more preferably 1 ns or less and directing the laser irradiation onto the optical element for the EUV wavelength range.

The inventors realized that one underlying problem exacerbating modifications of optical elements (for the EUV wavelength range) relates to the following: When processing an optical element using a laser to change the reflectivity in certain areas of the optical element, unwanted displacements of structures on the surface of the optical element may be generated, as the energy input into the stack shifts it in the direction of the laser irradiation.

The inventors further found that introducing femtosecond laser pulses as pulse sequences into the optical element, whereby the energy input may be variable over nanoseconds, at least reduces the unwanted displacement of structures (e.g., absorber material) on the optical element. This discovery is based on the understanding of the underlying physical processes following absorption of light (of the laser irradiation) within the optical element: The absorption of laser energy by free electrons occurs at a rate of uₑₑ=10¹⁴ s⁻¹, which translates to ca. 10 fs. The absorption of laser irradiation raises the electron temperature Tₑ to ca. 10,000 K while, initially, the lattice temperature of the optical element Tᵢ remains at ca. 300 K, when the optical element is at room temperature. Subsequently, the electrons transfer their energy to the lattice with a rate of uₑᵢ≈10¹² s⁻¹, which translates to ca. 1 ps. This is the specific time of metal heating. The absorbed energy then dissipates within the material according to the thermal diffusion coefficient of the material composition of the optical element. As described herein, typical optical elements may, e.g., comprise Mo and Si with diffusion coefficients D_{Mo}=0.54 cm²/s and D_{Si}=0.88 cm²/s. The diffusion (described by the equation t≈L²/D) thus typically occurs on longer timescales than 1 ps for diffusion lengths L of 7 nm or more. The invention accounts for the relevance of the different timescales of the underlying physical processes as described herein:

Especially, the first and second pulse being separated by a time of 100 ns or less proved to allow for improved results in modification of the optical element. Keeping the time between the pulses sufficiently short may allow to induce (thermal) energy of the second pulse into the optical element shortly after the first pulse when the treated optical element has not yet thermally equilibrated (e.g., via thermal diffusion). In detail, experiments with a pulse sequence comprising two pulses could achieve a 50% higher temperature at 200 nm depth within the optical element than in a control experiment with only one pulse (i.e., no pulse sequence) at essentially the same level of damage (e.g., comprising compaction and/or unwanted shifts of absorber elements thereon), and thus the effect reaches more deeply into the treated surface. Further experiments and test simulations show that even better results can be achieved by providing longer pulse sequences. In detail, longer pulse sequences may comprise three, four, five, or more pulses, e.g. in each pulse sequence.

The method for treating the optical element may be understood as to treat the optical element at least by directing the laser irradiation onto the optical element. The treating may comprise changing at least one characteristic of the optical element in at least one region of the optical element onto which the laser irradiation is directed. For example, the treating may comprise adjusting the reflectivity of at least a part of the optical element such as to fine-tune the reflective properties of the optical element, e.g., to achieve an essential homogeneous reflectivity (e.g., with variations of the absolute reflectivity of 1% or less, 0.1% or less, or 0.01% or less) in at least the part of the optical element. In one typical example, the treating may comprise, e.g., reducing a reflectivity of the optical element in irradiated region(s), creating a black border, being a border that reflects only very little (EUV) radiation, on the optical element, as described in more detail herein.

Generally, a pulse sequence may be understood as a plurality of pulses, wherein the time between two consecutive pulses is less than 100 ns. Vice versa, two pulses that are temporally apart by 100 ns or less may be seen as comprised in the same pulse sequence. Typically, the time between two consecutive pulse sequences is at least three-times longer than the duration of the pulse sequence. In an example wherein the pulse sequences are emitted at a frequency of 100 kHz (which corresponds to a period of 10 μs), the pulses of one pulse sequence may lie within a time window of 100 ns and the time between consecutive pulse sequences may be at least 900 ns. In other examples, however, it is also possible that the pulses of a pulse sequence have a longer separation time, e.g., above 100 ns.

The EUV wavelength range may, e.g., comprise wavelengths between 10 nm and 121 nm, preferably between 10 nm and 20 nm, more preferably between 10 nm and 15 nm.

Herein, a pulse sequence may comprise two or more pulses, each pair of which may be identical or vary in at least one pulse parameter. The at least one pulse parameter may comprise, e.g., a pulse length (e.g., expressed through the full width half maximum of the pulse), an intensity (e.g., expressed through the maximum amplitude of the pulse and/or the total energy of the pulse), a temporal pulse shape (e.g., an essentially Gaussian shape, a triangular shape, etc.), and/or a spatial pulse shape (e.g., a pulse cross section comprising a two-dimensional gaussian distribution or any other regular or unregular shape).

Typically, the pulses of the pulse sequence may be essentially (temporally) equidistant. The pulses of the pulse sequences may be emitted at a certain frequency and/or in a non-periodic (temporal) pattern.

In some examples, the same pulse sequence may be repeated at a certain frequency, e.g., at a frequency of 100 kHz (which corresponds to a period of 10 μs), for a predetermined time.

In one example, the optical element for the EUV wavelength range may comprise a multilayer system and optionally an absorber layer at a frontside of the optical element for the EUV wavelength range. The absorber layer may, e.g., be patterned, preferably comprise a 2D-pattern in the plane of the absorber layer. The multilayer system may, e.g., pose a Bragg mirror and/or be configured to reflect light in the EUV range, preferably between 10 and 20 nm.

For example, the multilayer system may comprise stacked molybdenum (Mo) and silicon (Si) layers. E.g., the Mo-layers may have an average thickness between 2 nm and 4 nm and/or the Si-layers may have an average thickness between 3 nm and 5 nm. The period (in this example between 5 nm and 9 nm) may directly translate to the wavelength maximum of the multilayer system's reflectance. Typical multilayer systems for reflection of 13.5 nm light may comprise ca. 2.9 nm tick Mo-layers and 4.0 nm thick Si-layers.

The absorber layer may, e.g., comprise a material that is opaque for EUV light and/or have an average thickness between 10 nm and 200 nm, preferably between 50 nm and 100 nm. In such exemplary optical elements, directing laser irradiation onto the optical element may, e.g., induce Mo—Si diffusion and/or MoₓSi_{y}-formation. These two processes both may result in a blurring of the layers of the multilayer system (as shown, e.g., in FIG. 4) and thus induce a change (e.g., a reduction) of reflectivity.

The absorber layer may, e.g., in the example of the optical element being a photolithography mask, be decisive for the pattern imprinted from the mask onto another structure. Thus, it is highly important to not adversely affect the absorber pattern in the method described herein. When compaction occurs, absorber pattern elements may shift due to the induced strain thereon which damages the optical element. The nominal size of the structural elements generated by the absorber pattern in a photoresist may be called critical dimension (CD). This size and its variation (CDU Critical Dimension Uniformity) are central parameters for the quality of a photolithography mask. Thus, the method described herein may significantly improve critical dimension control by avoiding or managing compaction effects which in turn has a positive effect on CD.

The pattern on the mask may be transferred onto the wafer via a lithography system. As such lithography system typically may work in the EUV range, these may be purely catoptric/reflective systems. On the wafer, a photosensitive resist may be exposed to the image of the mask determined by the absorber pattern. The region on the mask containing the patterns is typically surrounded by a border region, the so-called black border which may have a reflectance as low as possible such that said black borders reflect only very little (EUV) radiation. Problems arise when said black border are not perfectly black. At the same time, however, the black borders must be generated carefully, i.e., without damaging the absorber layer. The method described herein may—when used for black border generation-achieve just that.

In some examples, the optical element for the EUV wavelength range may comprise a mask, preferably wherein the optical element for the EUV wavelength range comprises a (EUV) photolithography mask.

The mask may be a (EUV) photolithography mask. The (EUV) photolithography mask may have an aspect ratio of between 1:1 and 1:4, preferably between 1:1 and 1:2, most preferably of 1:1 or 1:2. The (EUV) photolithography mask may have a nearly rectangular shape. The (EUV) photolithography mask may be preferably 5 to 7 inches long and wide, most preferably 6 inches long and wide. Alternatively, the (EUV) photolithography mask may be 5 to 7 inches long and 10 to 14 inches wide, preferably 6 inches long and 12 inches wide.

In some examples, the method may further comprise receiving error map information of the optical element. The providing the pulsed laser irradiation may, e.g., be based at least partly on the error map information.

The error map information may relate to an error map of the optical element or at least a part of the optical element. The error recorded in the error map may, e.g., comprise a reflectivity and/or other parameters described herein in reference to the optical element. In some examples, the error map may comprise information on a local deviation of a reflectivity from a desired (homogenous) reflectivity value. For example, it may be the goal of the method to reduce reflectivity variations of the optical element across the region covered by the map. The error map (information) may be provided and/or measured by the same apparatus and/or an apparatus different from the apparatus executing the method described herein.

Using error map information may allow a reliable repair of a reflectivity error of the optical element. For example, a reflectivity may be restored such that a deviation from a specified reflectivity is below a predetermined threshold throughout a (front-) side of the optical element.

In some examples, providing the pulsed laser irradiation based at least partly on the error map information may comprise adapting a pulse power, a pulse pitch, and/or a pulse diameter (laser beam diameter) of the pulsed laser irradiation locally according to the error map information.

In one example, a wavelength of the pulsed laser irradiation may be between 400 and 1500 nm, preferably between 700 nm and 1100 nm.

Working in this wavelength range is advantageous in various aspects: On the one hand, many substrates (e.g., comprising quartz) and/or coatings (e.g., comprising tantalum boride TaB) that may be used for optical elements as described herein are typically sufficiently transparent for the indicated wavelength ranges. This allows for treatment of the parts of the optical element in transmission through such substrates and/or coatings. On the other hand, there are various laser sources that may provide high-quality laser irradiation in this wavelength range and may be available at low costs. In one example, a Yb:KGW and/or a Yb fiber laser operating around 1000 nm wavelength may be used for the methods and apparatuses described herein. In another example, a titanium-sapphire laser (i.e., Ti:Al₂O₃ lasers) being a tunable laser emitting red and near-infrared laser irradiation in the range from ca. 650 nm to 1100 nm, may be used for the methods, apparatuses, and applications described herein.

For example, the repetition rate of the pulsed laser irradiation may be between 1 kHz and 1 MHz, preferably between 50 KHz and 200 kHz. A laser pulse length of the pulsed laser irradiation may be in the femtosecond range, preferably between 10 fs and 1000 fs, more preferably between 80 fs and 300 fs. The pulse sequence may, e.g., be repeated at a repetition frequency as described herein.

As absorption of laser energy by free electrons occurs at a rate of uₑₑ≈10¹⁴ s⁻¹, which translates to ca. 10 fs, it is particularly advantageous to use femtosecond laser pulses as these allow for localized heating.

These pulse parameters may, e.g., be achieved by laser sources comprising mode-locked oscillators. These may generate ultrashort pulses with the above pulse length. The repetition rate may, e.g., be determined by the round-trip optical path of the laser source, e.g., a titanium-sapphire laser as described herein. Thereby, such laser irradiation may be provided in a relatively cheap and reliable way on the one hand. On the other hand, the inventors found that providing short pulses as described herein allows to reduce unwanted side effects that are commonly observed in control experiments with longer laser pulses (e.g., in the nanosecond range). Providing both, sufficiently short pulses and sufficiently high repetition rates allow to avoid such side effects while keeping the working times sufficiently short.

In some examples, the first pulse and the second pulse of the plurality of pulses may be separated by a time of at least 10 ns.

The inventors found that typical optical elements, e.g., comprising Mo—Si multilayer systems as described herein, have high absorption coefficients. Thus, laser irradiation used to modify the optical element is typically absorbed mostly at and near the irradiated surface of the irradiated optical element. Thus, deeper depths may not be predominantly treated directly by the laser irradiation but rather by thermal diffusion driven processes. However, deep depths may not always be reached. Especially when femtosecond laser pulses are utilized. In order to exploit the advantages of reduced side effects associated with such femtosecond laser pulses on the one hand but also treating deep depths of the optical element on the other hand, the inventors identified the importance of tailoring the sequence duration. E.g., for equidistant pulses (separated by a time interval Δt), the duration of a pulse sequence comprising n pulses, the duration of the pulse sequence may amount to (n−1)·Δt.

In detail, providing pulse sequences that are sufficiently long (e.g., 10 ns or more) could increase the temperature in deep depths of the optical element (e.g., at 200 nm depth) relative to the temperature reached at the irradiated surface of the optical element by more than an order of magnitude.

In some examples, the pulses of the plurality of pulses may be repeated at a frequency of 10 MHz to 1 GHz.

Such high (intra-sequence) repetition rate was shown to yield various advantages. On the one hand, such sequences may be provided with high accuracy and reliability. On the other hand, the high repetition rate (and thus the short times between consecutive pulses) is high enough (or short enough, respectively) to be on the same timescale as the underlying physical processes (e.g., heat diffusion within the optical element on the relevant length scales). Thus, one may optimize the efficiency of the treatment and/or modification of the optical element associated with said underlying physical processes.

Such pulse sequences may, e.g., be provided by a laser source comprising a so-called burst mode laser. The laser source may, e.g., comprise a Q-switched laser and/or a continuously operating mode-locked laser (e.g., as described herein). Such laser sources may, e.g., further comprise a pulse picker, an optical modulator with a continuously variable transmissivity, and/or an optical amplifier. In detail, for providing short pulses with a high repetition rate, the laser source (e.g., comprising a mode-locked laser) may further comprise a pulse splitter, which may be configured to convert a pulse emitted by the laser source into a sequence of pulses (e.g., 2, 4 or 8 pulses). In general, the laser source may comprise one or more of the following components: a laser medium (e.g., a material that amplifies light to produce laser irradiation; e.g.: for solid-state lasers: Nd:YAG (Neodymium-doped Yttrium Aluminum Garnet), for gas lasers: CO₂ (Carbon Dioxide), HeNe (Helium-Neon), for semiconductor lasers: GaAs (Gallium Arsenide), for dye lasers: Rhodamine 6G), a pump source (e.g., an energy source used to excite the laser medium; e.g.: an electrical discharge unit (for gas lasers), a flash lamp and/or an arc lamp (for solid-state lasers), a laser diode (for pumping other lasers)), an optical resonator (e.g., a set of mirrors that form a cavity to amplify the light; e.g.: Fabry-Pérot resonator (e.g., two parallel mirrors), a ring resonator (e.g., a series of mirrors arranged in a loop)), a Q-switching mechanism (e.g., a mechanism to produce pulsed laser output by modulating the quality factor (Q) of the optical resonator; e.g.: an acousto-optic Q-switch, an electro-optic Q-switch, a mechanical Q-switch), a mode-locking mechanism (e.g., a technique to generate ultra-short pulses by locking the phases of different frequency modes; e.g.: active mode-locking (using an external modulator), passive mode-locking (using a saturable absorber)), a cooling system (e.g., a system to dissipate heat generated by the laser; e.g.: water cooling, air cooling, thermoelectric cooling), a power supply: (e.g., a supply that provides the necessary electrical power to the pump source and other components; e.g.: a DC power supply, an AC power supply with rectifier(s)), control electronics (e.g., circuitry to control and stabilize the laser operation; e.g.: microcontrollers, feedback control systems), a beam delivery system (e.g., components to direct and/or shape the laser beam; comprising, e.g.: mirror(s), lens(es), and/or beam expander(s)), and/or a safety mechanisms (e.g., features to ensure safe operation of the laser; e.g.: interlock systems, beam shutters, warning lights). These components may work together to produce and control the pulsed laser irradiation as described herein.

In some examples, at least one of the pulses may comprise at least one sub-sequence comprising a plurality of sub-pulses. For example, a first sub-pulse and a second sub-pulse of the plurality of sub-pulses may be separated by a time between 1 ps and 100 ns, preferably between 10 ps and 10 ns, more preferably between 100 ps and 1 ns.

By providing a sequence of pulses, wherein at least one of the pulses comprises another sub-sequence of pulses, the advantageous effects described herein may be further improved. In detail, the optical element may be treated even more efficiently while keeping the total energy deposited into the material (and potentially leading to negative side effects like compaction) low.

In some examples, the sub-pulses of the plurality of sub-pulses may be repeated at a frequency of 1 GHz to 100 GHz, preferably of 1 GHz to 10 GHz.

Such embodiments yield the advantages described herein with reference to the pulse sequences.

In some examples, the first pulse may comprise an intensity that is different from an intensity of the second pulse. The same may analogously apply to a first sub-pulse and a second sub-pulse of the sub-sequence.

The inventors found that thereby, the heat distribution induced within the optical element may be beneficially tailored as described herein, e.g., in reference to FIG. 12 and Table 3.

The intensity may, e.g., be defined by the energy per (sub-) pulse. For a pulse comprising a sub-sequence, the pulse intensity may correspond to the cumulative sub-pulse energies of the sub-sequence.

In detail, the sequence and/or sub-sequence may comprise a sequence envelope and/or a sub-sequence envelope. Such envelope may comprise a monotonic decrease or increase in pulse intensity within at least a part of the sequence and/or sub-sequence, respectively. In test measurements and simulations, especially monotonically decreasing envelopes were shown to achieve the desired heating of deep layers of the optical element and may be seen as particularly advantageous.

In some examples, the laser irradiation is directed onto a surface of the optical element for the EUV wavelength range with a pulse diameter (laser beam diameter) in the range between 1 μm to 100 μm.

A spot size of 1 μm to 100 μm allows to quickly treat relatively large areas of the optical element. Further, it is large compared to typical thicknesses of optical elements and/or the relevant heat diffusion lengths. This justifies the 1D modelling of heat propagation described herein, which forms part of the inventors understanding of the underlying processes essential for arriving at the invention described herein.

In some examples, the method may further comprise directing the laser irradiation onto a first region of the optical element for a first time period and directing the laser irradiation onto a second region of the optical element for the EUV wavelength range for a second time period.

Thereby, the optical element may be treated in a stepwise process. Typically, irradiating the first, second, and optionally third, fourth, and further regions may be performed in a scanning fashion, e.g., in a predetermined scanning pattern. This process may, e.g., be controlled by computing means, e.g., in an automized fashion. Thereby, the amount of work required may be significantly reduced and/or the accuracy and reliability of the method may be increased.

The first and second time periods may, e.g., have an equal duration. In one example, the first time period starts at a start time t=0 s, and ends at t=x s, the second time period may start at t=x s and end at t=2*x s (e.g., x may be equal to 1 ms, or 1 s, for example). In other examples, the duration of the first and second time intervals may differ.

In some examples, the first region and the second region differ at least partly from each other. Differing at least partly may imply that there is no full overlap of the first and second regions. E.g., a maximum overlap of 90% (e.g., calculated by conventional geometric metrics, e.g., as the area of overlap normalized to an average of the areas of the two regions) may be required for two regions to be seen as to differ at least partly. In some examples, the first and second regions may differ in full (i.e., have no overlap).

The pulsed laser irradiation may, e.g., be directed in a step-wise process onto specific points on the optical element. The points may, e.g., be arranged in a regular point pattern (e.g., a grid) or an irregular point pattern on the optical element. The positions of the points may be predetermined and/or adjusted (e.g., in a closed loop) during execution of the method described herein. In this example, a region may, e.g., be defined as a cell of the grid around a point of the grid. The cell assigned to one point may, e.g., be a so-called Voronoi cell, consisting of all space in the plane closer to that point than to any other point of the point pattern. For example, the pulses of one or more pulse sequences may be applied on each point.

In some examples, the laser irradiation (comprising a plurality of pulse sequences) may continuously scan the optical element such that the position on which the pulses are applied moves, e.g. from one pulse in a pulse sequence to another pulse in the same pulse sequence. For example, the laser irradiation may be directed on an optical element that moves, e.g., continuously (with a scanning speed). E.g., it may move such that subsequent pulses of the pulse sequence overlap only partly. Typically, the scanning speed may be slow enough that subsequent pulses of one or more pulse sequences overlap by more than 50%, preferably more than 90%, more preferably by more than 95%, most preferably more than 99%. In such examples, a first region may be defined as any arbitrary region on the optical element. Then, the first time period may be understood as the time period it takes the pulsed laser irradiation to scan across said first region. For example, a region can be defined as a rectangular shaped area the side lengths of which correspond to diameters of the individual pulses (for example, a square shape of 10 μm×10 μm may be used for a laser irradiation spot size of 10 μm, and non-square shapes may be used for non-circular spot sizes). If, for example, the scanning speed is 5 μm/s, the first time period required for scanning the first region may be 2 s (lasting from t=0 s to t=2 s). The same may apply analogously to the second region and the second time period. In the above example, if the second region also comprises a square shaped area of 10 μm×10 μm, the second time period required for scanning the second region may also be 2 s (lasting from t=2 s to t=4 s).

In some examples, the laser irradiation directed onto the first region and the laser irradiation directed onto the second region differ in one or more of: a pulse power, a pulse pitch, and a pulse diameter (laser beam diameter).

This may provide a particularly advantageous and accurate option to treat the optical element with high spatial resolution. The pulse power may refer to the energy delivered by the laser irradiation per unit time. The pulse pitch may relate to the spatial distance (e.g., in the plane of the optical element) between neighboring laser pulses (e.g., of neighboring cells as described herein). It may influence an overlap of pulses, and a treatment uniformity. The pulse diameter (laser beam diameter) may refer to the width or size of the irradiated target surface (i.e., the optical element), typically measured at the point where the beam's intensity falls to a FWHM or another specified percentage (e.g., 1/e²) of its maximum. It determines the area affected by each pulse and contributes to the resolution of the laser processing. In examples, in which the laser irradiation continuously scans the optical element, a scanning speed with which the laser irradiation scans the optical element may be varied instead of the pulse pitch.

In some examples, the method may further comprise adjusting the pulse power, the pulse pitch, and/or the pulse diameter (laser beam diameter) of the laser irradiation directed onto the first region and of the laser irradiation directed onto the second region may be adjusted according to a predetermined function of the error map information.

For example, the pulse power, the pulse pitch, and/or the pulse diameter (laser beam diameter) may be varied between the first and second regions based at least in part on the error map information and/or the predetermined function that may be obtained through calibration. The error map may comprise information on the first and second regions as well as, optionally, on one or more further regions. Preferably the error map information comprises information on essentially the whole optical element (e.g., excluding border regions that are not of interest for the function of the optical element). E.g., when the error map (information) indicates that the first region requires a first (higher) reflectivity reduction and that the second region requires a second (lower) reflectivity reduction, the first region may be processed with a laser irradiation of a first laser power and the second region may be processed with a laser irradiation of a second laser power. The second laser power may be lower than the first laser power. Additionally or alternatively, the pulse pitch may be increased in the second region and/or the pulse diameter (laser beam diameter) may be increased in the second region.

For example, directing the laser irradiation onto a region of the optical element may comprise directing the laser irradiation onto a backside of the optical element (cf. FIG. 3).

In backside processing, advantageously the laser irradiation does not pass the absorber layer as described herein, which may have different pattern densities on the order of magnitude of typical laser irradiation spot sized as described herein. Thus, backside processing may be performed at high accuracy and reliability and does not require for, e.g., any pattern density-dependent correction of the laser power.

In some examples, the laser irradiation directed onto the optical element may be adapted to treat a portion of the optical element near the absorber layer of the optical element, preferably a portion (e.g. of the multilayer system) spaced from the absorber layer by 200 nm or less, 100 nm or less or 30 nm or less.

By means of the short separation time between first and second pulses (and optionally further pulses), said range (in the stacking direction of the multilayer system) of portions can be reached, even when irradiating from the backside. This allows to combine the advantages of backside irradiation with the intended treatment of multilayers close to the absorber layer. The distances of 200 nm or less, 100 nm or less or 30 nm or less may be measured from the outermost point of the multilayer system from the surface closest to the absorber layer. Treating a portion of the multilayer system may comprise locally affecting the integrity of at least two adjacent layers, such that its reflectivity is lowered.

In another example, directing the laser irradiation onto a region of the optical element may comprise directing the laser irradiation onto a frontside of the optical element (cf. FIG. 2).

In frontside processing, advantageously the pulse energy is predominantly absorbed by the frontside layers of the optical element, which are typically those layers that are desired to be modified/treated in the method described herein.

The method may, for example, further comprise reducing the reflectivity of the multilayer system of light in the EUV range by 0% to 10%, preferably by 2% to 8%, shifting the wavelength of maximum reflectivity by 0 nm or more and/or 1 nm or less, preferably by 0.1 nm or more and/or 0.5 nm or less, and/or keeping a registration change below 20 nm, preferably below 10 nm, more preferably below 6 nm, or below 1 nm, or below 0.5 nm, e.g., for an EUV reflectivity reduction of at least 6%. Additionally or alternatively, the method may, for example, further comprise reducing the reflectivity of the multilayer system of light in the EUV range by 0% to 10%, preferably by 2% to 8%, shifting the wavelength of maximum reflectivity by 0 nm or more and/or 1 nm or less, preferably by 0.1 nm or more and/or 0.5 nm or less, and/or keeping an (uncorrectable) registration error below 20 nm, preferably below 10 nm, more preferably below 6 nm, or below 1 nm, or below 0.5 nm, e.g., for an EUV reflectivity reduction of at least 6%. For example, the registration change may pertain to one or more pattern elements of an absorber layer at a frontside that may be arranged on the multilayer system (with one or more optional layers in between, such as a capping layer).

These values proved to be sufficient to achieve the goals of the method described herein, on the one hand, and not harming the optical element, e.g., the absorber element(s)/pattern, on the other hand.

The registration change may, e.g., be a non-linear function of the induced EUV reflectivity reduction. The inventors tested various pulse sequences and recorded the registration change per induced EUV reflectivity reduction. Examples are provided in Table 1:

TABLE 1

| Pulse | 3 Sigma (%) |
|---|---|
| fs SP | 100% |
| P5N1WF1 | 33.7% |
| P10N1WF1 | 37.8% |
| P10N2WF1 | 30.3% |
| P10N3WF1 | 27.0% |
| P10N10WF2 | 19.7% |

In Table 1, 3Sigma of registration for a reduction of ˜6% EUV reflectivity is shown relative to the change when using a prior art fs SP.

In Table 1, the abbreviations relate to the following pulse sequences:
Single fs pulses (SP) as per the prior art,
a pulse sequence of 5 fading fs pulses, separated by 400 ps, wherein “fading” implies that the pulse energy decreases monotonically within the pulse sequence (P5N1WF1),
a pulse sequence of 10 fading pulses, separated by 400 ps (P10N1WF1),
two pulse sequences P10N1WF1, separated by 16 ns, wherein the pulse energies of the pulses of the second sequence are lower than the pulse energies of the corresponding pulses of the first sequence, such that there are “fading” pulse sequences (P10N2WF1),
three pulse sequences P10N1WF1 separated by 16 ns, in the form of “fading” pulse sequences (P10N3WF1), and
ten pulse sequences P10N1WF1 separated by 16 ns, but in form of pulse sequences, wherein the pulse power reduces more slowly from pulse sequence to pulse sequence (P10N10WF2).

As can be seen from Table 1, the registration (3Sigma) can be strongly reduced by moving from the prior art fs SP to more complex pulse sequences.

In general, the pulse sequences of the examples described herein may be separated by 16 ns and/or the pulses of each sequence may be separated by 400 ps.

For example, the laser pulse may be directed onto the optical element at coordinates (x, y). The “registration change” may refer to the change in the position of the feature of the absorber layer 150 at coordinates (x, y). E.g., it may be shifted to the coordinates (x+x1, x+y1), wherein x1 and y1 describe the amount by which the feature of the absorber layer 150 may shift according to the induced registration as described herein. The “registration change” may particularly refer to movements in a horizontal direction (relative to the surface of the optical element).

In another example, the method may, for example, further comprise reducing the reflectivity of the optical element of light in the EUV range by at least 40% and/or shifting the wavelength of maximum reflectivity by at least 1 nm.

The reduction in reflectivity R % may, e.g., be defined as the ratio between the reflectivity at 13.5 nm of the multilayer system before and after treating it by the method described herein: R_{%}=R_{after}/R_{before}. Typically, the reflection spectrum of a reflective optical element for the EUV wavelength range has a reflectance maximum at a certain wavelength for a certain angle of incidence. The wavelength of maximum reflectivity may, e.g., determined by fitting a peak function (e.g., a Gauss peak) to said spectrum and/or by simply extracting the wavelength position of the highest value of the spectrum. Typically, the wavelength of maximum reflectivity before treating the optical element according to the method described herein may be at or around 13.5 nm (e.g., between 12 nm and 14 nm). Typical angles of incidence may, e.g., be in the range of 0° to 45° relative to the surface normal of the optical element.

The method described herein may, for example, further comprise adjusting at least one parameter of the pulsed laser irradiation based at least in part on the dimensions and/or the material properties of the optical element for the EUV wavelength range.

For example, one may consider the timescales associated with thermal diffusion within the optical element. Table 2 lists some exemplary lengths for thermal diffusion in Mo—Si multilayer systems associated with timescales between 10 ps and 10 μs. Based thereon, it becomes apparent that longer (e.g., ns) pulses allows to get a more homogeneous heating of the optical element due to heat propagation in optical element. It may therefore be beneficial to increase the effective pulse width in order to heat deep layers of the optical element to be treated. This may particularly be relevant for backside irradiation as described herein to reduce uncorrectable registration impact for back side processing. However, simply increasing the pulse length to nanosecond pulses may not be sufficient as it also may come along with the disadvantageous side effects described herein like compaction.

TABLE 2

| | |
|---|---|
| t | L (nm) |

| | | |
|---|---|---|
| 10 | ps | 30 |
| 0.4 | ns | 188 |
| 1 | ns | 297 |
| 10 | μs | 29665 |

As described herein, the at least one pulse parameter may comprise, e.g., a pulse length, the intensity, a temporal pulse shape, a sequence envelope, a sub-sequence envelope, and/or a spatial pulse shape. In detail, it may be particularly advantageous to adjust the parameter of the pulsed laser irradiation to the depth at which one wants to modify the optical element. Some aspects that may be considered are described in reference to FIGS. 8 and 9.

Generally, the at least one parameter of the pulsed laser irradiation may be chosen such as to control the depth-dependent thermal distribution within the optical element. E.g., the method described herein may induce a certain temperature at a depth (of, e.g., 50 nm, 100 nm, 150 nm, 200 nm or more) within the optical element that amounts to at least 25%, 50% or 75% of the induced surface temperature at the surface of the optical element the laser irradiation is directed onto. Some examples of how to achieve this are described herein in reference to FIG. 11. The depth may, e.g., be measured in an orthogonal direction relative to the surface and/or from the irradiated region of the surface of the optical element and/or of the multilayer system comprised therein.

In some examples, the method may further be adapted to provide an essentially homogeneous registration error and/or a small uncorrectable registration error and/or a small overlay error over at least a part of the optical element, e.g. over the entire optical element.

For example, the adjustable registration-to-reflectivity change ratio may be adapted for the treatment of each region such that the desired reflectivity changes may be induced on the one hand, and, on the other hand, a negligible uncorrectable registration impact is achieved in at least some, most, or all treated regions, preferably across the whole optical element (e.g., across its entire front-side). A homogenous registration may relate to a scenario in which every feature is displaced, such that the displacement can essentially be corrected by setting at a scanner, when using the optical element during lithography. In some examples, not the whole optical element may be treated by the method described herein. Optionally, remaining (untreated) regions may be treated by another method that may not or only moderately affect reflectivity but change the registration in said initially untreated regions such that a small uncorrectable residual registration may be achieved throughout the optical element. The other method may, e.g., be (or comprise at least one step of) a method as described in EP 4 302 156 A1, in which a conventional pulsed laser irradiation (without necessarily requiring pulse sequences as in the present invention) may be focused into a substrate of the optical element, e.g., from a backside, such that the reflectivity (e.g., at a frontside) is essentially unaffected. Additionally or alternatively, the other method may, e.g., be (or comprise at least one step of) a method as described in EP 4 471 499 A1, which relates to applying an electromagnetic radiation to a mask to evoke a material change within the mask such that at least one property of the mask is modified. Further examples for the other method may further be based at least in part on the according technical principles described in the following documents: U.S. Pat. No. 9,436,080 B2, US 2020/124 959 A1, US 2012/009 511 A1, EP 1 649 323 A2 (which are incorporated herein by reference in their entirety).

In some examples, the method may further comprise creating a black border on the optical element, preferably by reducing a reflectivity of the optical element in at least one region of the optical element onto which the laser irradiation is directed, wherein the region at least partly extends along a rim of the optical element, for example forms a closed loop along a rim of the optical element.

A second aspect of the invention relates to a computer program comprising instructions for carrying out the steps of the method described herein.

Providing a computer program, e.g., for (at least partly) automatically operating an apparatus as described herein, may increase the accuracy, reliability and treatment speed of the method described herein. Further, it may significantly reduce the amount of labor for treating optical elements.

A third aspect of the invention relates to an apparatus for treating an optical element for the EUV wavelength range, wherein the apparatus comprises a laser source configured to provide a pulsed laser irradiation, wherein the pulsed laser irradiation comprises a plurality of pulse sequences, each pulse sequence comprising a plurality of pulses, wherein a first pulse and a second pulse of the plurality of pulses are separated by a time of 100 ns or less, and means for directing the laser irradiation onto the optical element for the EUV wavelength range. The means for directing the laser irradiation onto the optical element may, e.g., comprise one or more lenses and/or one or more mirrors.

In some examples, the apparatus may further comprise a control means configured to control the apparatus to, preferably automatically, execute the steps of the method described herein. For example, the control means can include a computer, a processor and/or similar hardware and/or software. The control computer and/or the processor may be configured to receive user input (e.g., via a mouse, a keyboard, a touchscreen, a camera, a microphone, and/or other input means). The computer and/or processor may process said input(s) and/or provide control output(s) being human- and/or machine readable instructions that may comprise instructions for controlling (e.g., keeping constant or changing) at least one parameter of the laser irradiation described herein and/or for controlling the movement of the optical element relative to the laser irradiation, e.g., as described herein. E.g., the control means may control the laser irradiation by controlling the used laser source. This may, e.g., comprise controlling at least one laser parameter (e.g., by varying it or keeping it constant) and/or controlling the region onto which the laser irradiation is directed (e.g., comprising an automated scanning).

In some implementations, the apparatus may include a light or irradiation source to generate light or irradiation, an image sensor (e.g., CCD and/or CMOS sensor) having an array of individually addressable sensing elements for capturing images of a sample, and optics (e.g., one or more lenses, mirrors or reflecting surfaces, filters, and/or image stops) to direct and/or focus light or irradiation from the one or more light or irradiation source to the sample, and optionally from the sample to the image sensor, e.g., for obtaining the error map (information). In some implementations, the apparatus can include a data processor and a storage device. The data processor in the apparatus can provide instructions to the physical means of the apparatus to execute the steps of the method described herein. The storage device can store the computer program as described herein. In some implementations, the apparatus can include one or more computers that include one or more data processors configured to execute one or more programs that include a plurality of instructions according to the principles described above. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

The processing of data described in this document, such as the steps of the method, the processing of the error map for obtaining the error map information, can be carried out using one or more computers, which can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

The embodiments of the present invention that are described in this specification and the optional features and properties respectively mentioned in this regard should also be understood to be disclosed in all combinations with one another. In particular, in the present case, the description of a feature comprised by an embodiment-unless explicitly explained to the contrary-should also not be understood such that the feature is essential or indispensable for the function of the embodiment.

In general, any steps of the method described herein may be implemented as instructions of the computer program and/or as means of the apparatus described herein, and vice versa.

### BRIEF DESCRIPTION OF DRAWINGS

FIG. 1 shows an exemplary EUV photolithography mask comprising a multilayer system.

FIG. 2 shows the exemplary EUV photolithography mask of FIG. 1 processed by frontside laser irradiation.

FIG. 3 shows the exemplary EUV photolithography mask of FIG. 1 processed by backside laser irradiation.

FIG. 4 shows a high-resolution transmission electron micrograph of an exemplary multilayer system irradiated with femtosecond laser pulses at a fluence of 280 mJ/cm².

FIG. 5 shows four exemplary reflectance spectra of treated and untreated multilayer systems.

FIG. 6 shows a microscopy image top view of a laser irradiation-treated exemplary multilayer system.

FIG. 7 shows an exemplary depth profile of a laser irradiation-treated exemplary multilayer system acquired by atomic force microscopy and one representative cut through the depth profile.

FIG. 8 shows a schematic representation of light reflection and absorption at different layers of an exemplary multilayer system.

FIG. 9 shows a schematic representation of the absorbed energy distribution in an exemplary multilayer system linked to the physical processes illustrated in FIG. 8.

FIG. 10 shows an exemplary laser irradiation intensity over time, wherein the laser irradiation comprises a sequence comprising a sub-sequence of sub-pulses.

FIG. 11 schematically shows five exemplary ways of controlling a sequence envelope.

FIG. 12 shows an exemplary relative temperature distribution as a function of depth into the multilayer system created upon different temporal pulse sequences.

### DETAILED DESCRIPTION

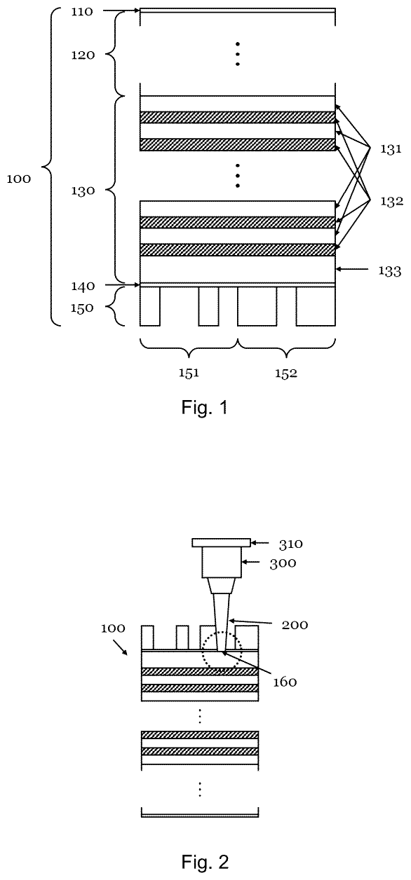

FIG. 1 shows an EUV photolithography mask 100 comprising a multilayer system 130 as one example for an optical element 100 as described herein. The optical element may comprise a layered architecture 100. In the example of FIG. 1, the layers may extend in the horizontal plane. The layers may typically have lateral dimensions in the horizontal plane that extend the thickness in the vertical direction (i.e., the stacking direction of the layers) by many orders of magnitude.

The exemplary optical element 100 comprises a backside coating 110 applied onto a substrate 120. The backside coating may, e.g., comprise TaB and/or have a thickness between 10 nm and 500 nm, preferably between 50 nm and 100 nm. The substrate may, e.g., comprise a low thermal expansion material and/or have a thickness in the mm range, preferably between 1 mm and 10 mm, more preferably between 6 mm and 7 mm. The three dots illustrate that the drawing of FIG. 1 is not scaled but the substrate may be much thicker than shown here.

The optical element 100 may further comprises a multilayer system 130 comprising two alternatingly stacked layers, a first layer 131 and a second layer 132. For example, the first layer 131 and the second layer 132 may comprise materials with different refractive indices. This allows them to form a reflective Bragg mirror, e.g., as described herein. The first layer 131 may, e.g., comprise Si and/or have a thickness of ca. 4.0 nm as shown in the example of FIG. 1. The second layer 132 may, e.g., comprise Mo and/or have a thickness of ca. 2.9 nm as shown in the example of FIG. 1. Again, the three dots illustrate that the drawing of FIG. 1 is not scaled but the multilayer structure 130 may be much thicker than shown here. Typically, multilayer systems 130 may comprise between 10 and 200 bilayers (e.g., each comprising one first layer 131 and one second layer 132), e.g., resulting in thicknesses of the multilayer system 130 in the nanometer range. The multilayer system may be terminated by a final layer 133. In the example of FIG. 1, the final layer 133 may comprise Si and/or have a thickness that is different from the first and/or second layer 131, 132 and/or may be between 3 nm and 11 nm. Other exemplary optical elements may, e.g., comprise three or more alternating layers.

The optical element 100 may, e.g., further comprise a cap layer 140. The cap layer 140 may, e.g., comprise ruthenium (Ru). The multilayer system 130 may thus be sandwiched between the substrate 120 and the cap layer 140. The cap layer 140 may be attached to the multilayer system 130 on the one side and to an absorber layer 150 on the other side.

The absorber layer 150 may be patterned such as to allow it to be used in a photolithography mask. It may comprise relatively densely-packed areas 152 (e.g., areas with 50% surface coverage or more) and less densely-packed areas 151 (e.g., areas with less than 50% surface coverage).

The exemplary optical element 100 of FIG. 1 may, e.g., be processed as described herein. Said processing may induce both, a change in EUV reflectivity (e.g., a reduction thereof), on the one hand, and a registration change/impact on the other hand. In the example of FIG. 1, a registration impact may include that any of the features (illustrated as rectangles) of the absorber layer 150 may shift either to the left or the right (and/or the shift inside or out of the plane of the 2D illustration of FIG. 1), e.g., within the plane of the surface of the optical element.

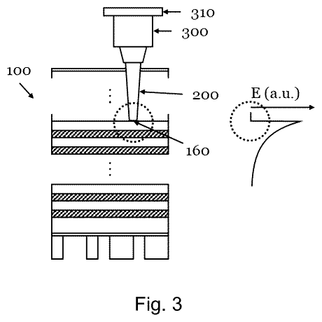

FIG. 2 shows the exemplary optical element 100 of FIG. 1 processed by frontside laser irradiation. FIG. 3 shows the exemplary optical element 100 of FIG. 1 processed by backside laser irradiation. In both cases, a laser source 300 providing the laser irradiation 200 is provided and directs the laser irradiation onto a region 160 of the optical element 100. The energy is absorbed mostly right at the region 160 of the multilayer system that is irradiated by the laser irradiation 200. This is illustrated schematically by the graph on the right of FIG. 3 showing how the deposited energy decreases with increasing depth into the optical element 100. This applies analogously for the scenario of FIG. 2 (frontside irradiation) and 3 (backside irradiation).

The laser source may, e.g., as shown in FIGS. 2 and 3, be mounted to a means for moving the laser source 310. The means for moving the laser source 310 may, e.g., comprise a two- and/or three-dimensional stage allowing the laser source to be moved relative to the optical element 100, e.g., in an automized way. This may, e.g., be controlled by an according computer program as described herein.

The laser source 300 may, e.g., further comprise means for directing 320 the laser irradiation onto the optical element which may, e.g., comprise one or more lenses and/or one or more mirrors.

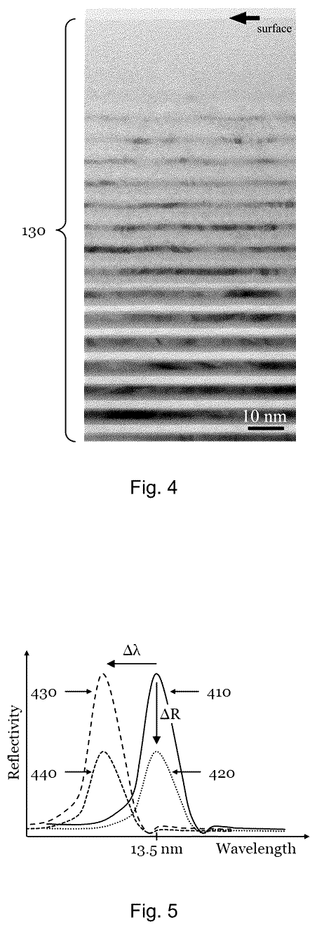

FIG. 4 shows a high-resolution transmission electron micrograph of an exemplary multilayer system 130 irradiated with femtosecond laser pulses at a fluence of 280 mJ/cm². The surface (at the top of FIG. 4) is treated by the laser irradiation (not shown). This treatment resulted in the diminishing of the layers of the multilayer system 130 near the surface while at the bottom, the individual layers are clearly visible as less energy was deposited there.

FIG. 5 shows four exemplary reflectance spectra of treated 420, 430, 440 and untreated optical elements 410.

The first reflectance spectrum 410 corresponds to an untreated optical element. The reflectance spectrum 410 comprises a high amplitude and is centered at around 13.5 nm.

The second reflectance spectrum 420 corresponds to a first treated optical element. The reflectance spectrum 420 comprises a reduced amplitude and is (like the reflectance spectrum 410 of the untreated optical element) centered at around 13.5 nm. This may, e.g., be achieved by the depletion of the layers of a multilayer system as, e.g., shown in FIG. 4. The reflectance spectrum 410 of the untreated optical element and the reflectance spectrum 420 of the first treated optical element thus essentially differ by an amplitude difference ΔR.

The third reflectance spectrum 430 corresponds to a second treated optical element. The reflectance spectrum 430 comprises essentially the same amplitude (like the reflectance spectrum 410 of the untreated optical element) and is centered at around a wavelength shorter than 13.5 nm. This may, e.g., be achieved by compaction of the layers of a multilayer system. The reflectance spectrum 410 of the untreated optical element and the reflectance spectrum 430 of the second treated optical element thus essentially differ by a wavelength shift AA.

The fourth reflectance spectrum 440 corresponds to a third treated optical element. The reflectance spectrum 440 comprises a reduced amplitude (e.g., achieved by the depletion of the layers) Further, it is centered at around a wavelength shorter than 13.5 nm (e.g., achieved by compaction of the layers). The reflectance spectrum 410 of the untreated optical element and the reflectance spectrum 440 of the third treated optical element thus essentially differ by an amplitude difference ΔR and a wavelength shift AA.

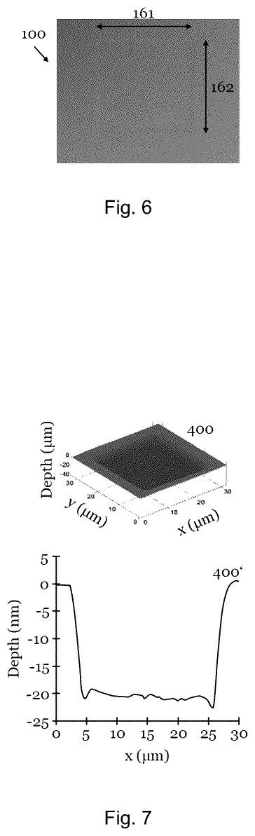

FIG. 6 shows a microscopy image top view of a laser irradiation-treated optical element 100 comprising a multilayer system acquired by optical microscopy. The treated area may be perceived as a square-shaped area with border lengths 161, 162 of ca. 20 μm each.

FIG. 7 shows an exemplary atomic force microscopy depth profile 400 of a laser irradiation-treated optical element 100 comprising a multilayer system acquired by atomic force microscopy and one representative cut 400′ through the depth profile. The cut 400′ illustrates the effect of compaction: the depth of the optical element within the treated area differs by ca. 20 nm from the untreated area. In some examples, when the laser pulses irradiate a portion of the optical element, the laser pulses may cause the structure and/or density of the portion of the optical element to change, resulting in compaction of the portion of the optical element in the vertical direction, causing the overall thickness of the portion of the optical element to be reduced.

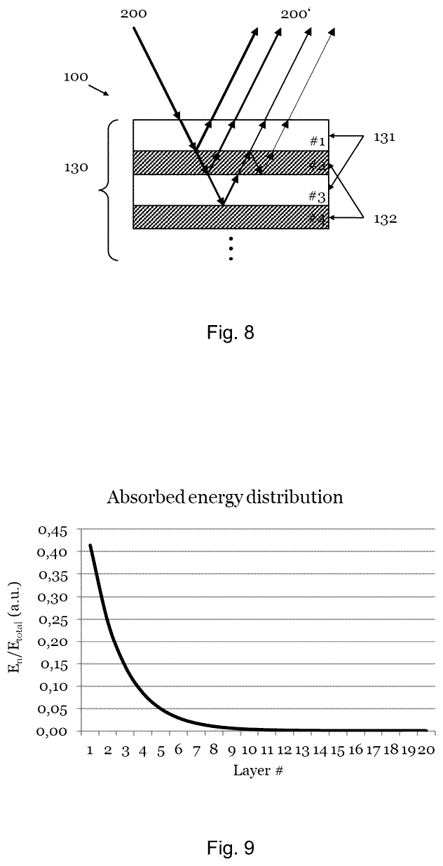

FIG. 8 shows a schematic representation of light reflection and absorption at different layers of an exemplary multilayer system 130 of an optical element 100. An exemplary Mo—Si multilayer system 130 of the optical element 100 may be characterized as shown in Table 3.

TABLE 3

| | h | | | z | ρ | C | Tₘ |
|---|---|---|---|---|---|---|---|
| | (nm) | n | k | (μm) | (g/cm³) | (J/gK) | (° C.) |
| Mo | 2.9 | 3.6371 | 3.365 | 0.0189 | 10.2 | 0.251 | 2623 |
| Si | 4.0 | 3.681 | 0.005 | 12.7324 | 2.329 | 0.7 | 1412 |
| Qz | | 1.4534 | 0 | | | | |

Table 3 relates to the thickness h, the index of refraction n (for 800 nm irradiation), the extinction coefficient k (for 800 nm irradiation), the penetration depth, at which light intensity drops e-times z, the density p, the heat capacity C, and the melting temperature Tₘ of the respective material. At 800 nm, Mo 132 absorbed light much more efficiently than Si 131. Following the equation for extinction (˜exp(−kz/λ)), the Mo layer practically absorbs almost all the energy. The reflectivity at the Mo—Si interface at 800 nm is ca. 0.174.

As a result, the intensity of light decreases the deeper the incoming laser irradiation 200 penetrates the optical element 130. The reflected light 200′ thus is also weaker, the deeper the interface it is reflected by. The underlying reason for this depth-dependence of the light intensity is the absorption by the Mo-132 and Si-layers 131.

FIG. 9 shows a schematic representation of the absorbed energy distribution in an exemplary multilayer system linked to the physical processes illustrated in FIG. 8.

While the first Mo-layer absorbs ca. 40% of the incoming energy, this ration drops to less than 25% for the second Mo-layer, less than 15% for the third Mo-layer and so on. The absorption by the Si-layers may be neglected in this model (cf. Table 3).

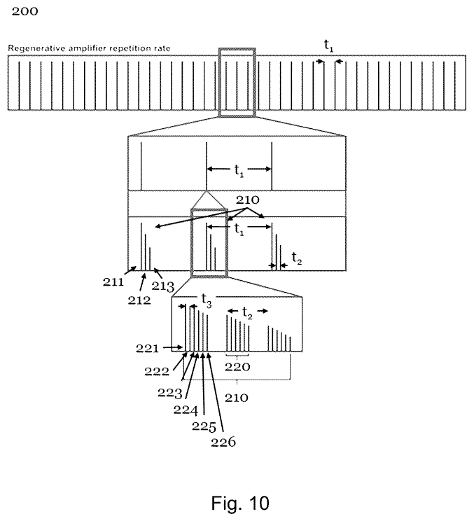

FIG. 10 shows an exemplary laser irradiation intensity over time, wherein the laser irradiation 200 comprises a sequence 210 comprising pulses 211, 212, 213. The time t₁ is the time between two consecutive (pulse) sequences 210 and the time t₂ is the time between two consecutive pulses 211, 212, 213. Optionally, each (or at least one) of the pulses 211, 212, 213 may comprise a sub-sequence 220 comprising a plurality of sub-pulses 221, 222, 223, 224, 225, 226. Time t₃ is the time between two consecutive sub-sequences 220.

In the example of FIG. 10, the envelope of the sequence 210 as well as of the optional sub-sequences is controlled to monotonically decrease the intensity of the pulses within each sequence 210 and within each sub-sequence 220.

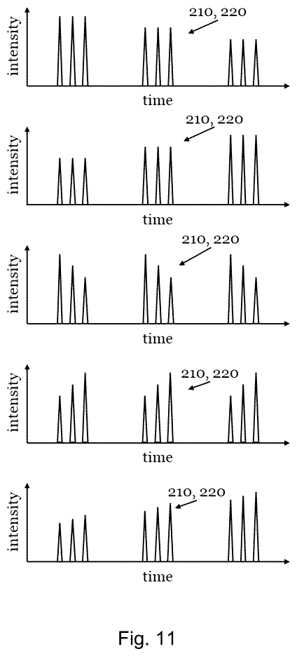

FIG. 11 schematically shows five exemplary ways of controlling the sequence envelope. The shown concept may analogously apply to an envelope control of a sequence 210 and/or a sub-sequence 220 as described herein.

The first panel shows that the intensity for all pulses is constant within a (sub-) sequence 210, 220 but decreases monotonically for the next (sub-) sequence(s) 210, 220.

The second panel shows that the intensity for all pulses is constant within a (sub-) sequence 210, 220 but increases monotonically for the next (sub-) sequence(s) 210, 220.

The third panel shows that the intensity decreases monotonically within a (sub-) sequence 210, 220 wherein subsequent (sub-) sequences 210, 220 have the same envelope.

The fourth panel shows that the intensity increases monotonically within a (sub-) sequence 210, 220 wherein subsequent (sub-) sequences 210, 220 have the same envelope.

The fifth panel shows that the intensity increases monotonically within a (sub-) sequence 210, 220 and increases monotonically across subsequent (sub-) sequences 210, 220 for a predetermined number of subsequent (sub-) sequences 210, 220 (in this example three).

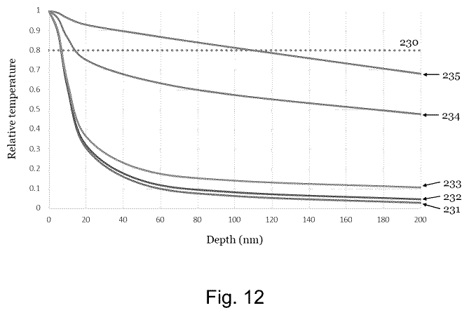

FIG. 12 shows exemplary relative temperature distributions 231, 232, 233, 234, 235 as a function of depth into the multilayer system created upon different temporal pulse sequences 210 and/or sub-sequences 220. Further, FIG. 12 shows a reference threshold 230 of 80% of the temperature at the irradiated surface of the treated optical element.

The first exemplary relative temperature distributions 231 may, e.g., be induced by single pulse irradiation (i.e., laser irradiation comprising no pulse sequence). It can be seen that all further irradiations result in improved relative temperature distributions 232, 233, 234, 235.

The second exemplary relative temperature distributions 232 may, e.g., be induced by a laser irradiation comprising a pulse sequence comprising two pulses separated by a time of 25 ns.

The third exemplary relative temperature distributions 233 may, e.g., be induced by a laser irradiation comprising a pulse sequence comprising ten pulses, wherein consecutive pulses are separated by a time of 25 ns.

The fourth exemplary relative temperature distributions 234 may, e.g., be induced by a laser irradiation comprising a pulse sequence comprising ten pulses, wherein consecutive pulses are separated by a time of 16 ns. Further, each pulse comprises a sub-sequence of ten sub-pulses, wherein consecutive sub-pulses are separated by a time of 0.4 ns.

The fifth exemplary relative temperature distributions 235 may, e.g., be induced by a laser irradiation comprising a pulse sequence comprising ten pulses, wherein consecutive pulses are separated by a time of 16 ns. Further, each pulse comprises a sub-sequence of ten sub-pulses, wherein consecutive sub-pulses are separated by a time of 0.4 ns. Additionally (and in contrast to the fourth exemplary relative temperature distribution 234), the intensity of the sub-pulses fades by 10% (of the intensity of the first sub-pulse of the sub-sequence) between consecutive pulses within the sub-sequence (i.e., a monotonically decreasing intensity throughout the sub-sequence).

Interestingly, one can see that the different aspects of the invention like adjusting the sequence duration, the time between pulses, and/or the envelope control may substantially improve the result achieved by the methods allowing to reach a more evenly distributed temperature throughout the treated optical element. The results are summarized in Table 4.

One can see that gradually the temperature distribution increases from example #1 to example #5 from FIG. 12. This may be quantified, e.g., by means of the ratio between the temperature at 200 depth and the temperature at the surface, i.e., 0 nm depth (T_{200 nm}/T_{0 nm}) or the depth at which the temperature drops to 80% of the temperature at the surface d_{80%}. Both measures are significantly increasing with the measures taken by examples #2-#5 compared to the reference example #1.

TABLE 4

| | | t₁ | | t₁ | | T_{200 nm}/ | d_{80%} |
|---|---|---|---|---|---|---|---|
| Example | n₁ | (ns) | n₂ | (ns) | Envelope | T_{0 nm} | (nm) |
| #1 (231) | 1 | — | — | — | — | 2.6% | 5 |
| #2 (232) | 2 | 25 | — | — | — | 4.3% | 6 |
| #3 (233) | 10 | 25 | — | — | — | 11% | 8 |
| #4 (234) | 10 | 16 | 10 | 0.4 | — | 47% | 13 |
| #5 (235) | 10 | 16 | 10 | 0.4 | yes | 68% | 108 |

Although the present invention is defined in the attached claims, it should be understood that the present invention can also be described in accordance with the following examples:

Example 1: A method for treating an optical element for the extreme ultraviolet (EUV) wavelength range, the method comprising:
providing a pulsed laser irradiation, wherein the pulsed laser irradiation comprises: a plurality of pulse sequences, each pulse sequence comprising a plurality of pulses; wherein a first pulse and a second pulse of the plurality of pulses are separated by a time of 100 ns or less; and
directing the laser irradiation onto the optical element for the EUV wavelength range.

Example 2: The method of example 1, further comprising:
receiving error map information of the optical element; and
wherein providing the pulsed laser irradiation is based at least partly on the error map information.

Example 3: The method of example 1 or 2, wherein the directing the laser irradiation onto the optical element comprises:
directing the laser irradiation onto a first region of the optical element for a first time period; and
directing the laser irradiation onto a second region of the optical for a second time period.

Example 4: The method of example 3, wherein the first region and the second region differ at least partly; and
wherein the laser irradiation directed onto the first region and the laser irradiation directed onto the second region differ in one or more of: a pulse power, a pulse pitch, and a pulse diameter.

Example 5: The method of example 4, directly or indirectly referred back to example 2, further comprising: adjusting the pulse power, the pulse pitch, and/or the pulse diameter of the laser irradiation directed onto the first region and of the laser irradiation directed onto the second region according to a predetermined function of the error map information.

Example 6: The method of any of examples 1-5, wherein the optical element for the EUV wavelength range comprises a multilayer system and optionally an absorber layer at a frontside of the optical element for the EUV wavelength range; wherein the multilayer system is configured to reflect light in the in the EUV range, between 10 and 20 nm.

Example 7: The method of any of examples 1-6, wherein the directing the laser irradiation onto the optical element for the EUV wavelength range comprises directing the laser irradiation onto a backside of the optical element for the EUV wavelength range

Example 8: The method of example 6 or 7, referred back to example 6, wherein the laser irradiation directed onto the optical element is adapted to treat a portion of the optical element near the absorber layer of the optical element, a portion spaced from the absorber layer by 200 nm or less, 100 nm or less or 30 nm or less.

Example 9: The method of any of examples 6-8, further comprising:
reducing the reflectivity of the multilayer system of light in the EUV range by 0% to 10%, preferably by 2% to 8%;
shifting the wavelength of maximum reflectivity by 0 nm to 1 nm, preferably by 0.1 nm to 0.5 nm; and/or
keeping a registration change below 20 nm for an EUV reflectivity reduction of at least 6%.

Example 10: The method of any of examples 1-9, wherein the optical element for the EUV wavelength range comprises a mask.

Example 11: The method of any of examples 1-10, further comprising:
creating a black border on the optical element by reducing a reflectivity of the optical element in at least one region of the optical element onto which the laser irradiation is directed, wherein the region at least partly extends along a rim of the optical element.

Example 12: The method of any of examples 1-11, wherein
a wavelength of the pulsed laser irradiation is between 400 and 1500 nm, preferably between 700 nm and 1100 nm;
the repetition rate of the pulsed laser irradiation is between 1 kHz and 1 MHz, preferably between 50 KHz and 200 kHz; and/or
a laser pulse length of the pulsed laser irradiation is in the femtosecond range, preferably between 10 fs and 1000 fs, more preferably between 80 fs and 300 fs.

Example 13: The method of any of examples 1-12, wherein the first pulse and the second pulse of the plurality of pulses are separated by a time of at least 10 ns.

Example 14: The method of any of examples 1-13, wherein the pulses of the plurality of pulses are repeated at a frequency of 10 MHz to 1 GHz.

Example 15: The method of any of examples 1-14, wherein at least one of the pulses comprises at least one sub-sequence comprising a plurality of sub-pulses;
wherein a first sub-pulse and a second sub-pulse of the plurality of sub-pulses are separated by a time between 1 ps and 100 ns; and/or
wherein the sub-pulses of the plurality of sub-pulses are repeated at a frequency of 1 GHz to 100 GHz, preferably of 1 GHz to 10 GHz.

Example 16: The method of any of examples 1-15, wherein the first pulse comprises an intensity that is different from an intensity of the second pulse.

Example 17: The method of any of examples 1-16, wherein the laser irradiation is directed onto a surface of the optical element for the EUV wavelength range with a pulse diameter in the range between 1 μm to 100 μm; and/or further comprising adjusting at least one parameter of the pulsed laser irradiation based at least in part on the dimensions of the optical element for the EUV wavelength range.

Example 18: Method of any of examples 1-17, wherein the method is further adapted to provide an essentially homogeneous registration over at least a part of the optical element.

Example 19: An apparatus for treating an optical element for the extreme ultraviolet (EUV) wavelength range, wherein the apparatus comprises:
a laser source configured to provide a pulsed laser irradiation, wherein the pulsed laser irradiation comprises:
a plurality of pulse sequences, each pulse sequence comprising a plurality of pulses; wherein a first pulse and a second pulse of the plurality of pulses are separated by a time of 100 ns or less; and means for directing the laser irradiation onto the optical element for the EUV wavelength range.

Example 20: The apparatus of example 19, further comprising a control means configured to control the apparatus to, preferably automatically, execute the steps of the method of any of examples 1-18.

A number of embodiments of the invention have been described. Nevertheless, it will be understood that various modifications may be made without departing from the spirit and scope of the invention. Accordingly, other embodiments are within the scope of the following claims.

What is claimed is:

1. A method for treating an optical element for the extreme ultraviolet (EUV) wavelength range, the method comprising:
providing a pulsed laser irradiation, wherein the pulsed laser irradiation comprises:
a plurality of pulse sequences, each pulse sequence comprising a plurality of pulses; wherein a first pulse and a second pulse of the plurality of pulses are separated by a time of 100 ns or less; and
directing the laser irradiation onto the optical element for the EUV wavelength range.

2. The method of claim 1, further comprising:
receiving error map information of the optical element; and
wherein providing the pulsed laser irradiation is based at least partly on the error map information.

3. The method of claim 1, wherein the directing the laser irradiation onto the optical element comprises:
directing the laser irradiation onto a first region of the optical element for a first time period; and
directing the laser irradiation onto a second region of the optical element for a second time period.

4. The method of claim 3, wherein the first region and the second region differ at least partly; and
wherein the laser irradiation directed onto the first region and the laser irradiation directed onto the second region differ in one or more of: a pulse power, a pulse pitch, and a laser beam diameter.

5. The method of claim 4, further comprising:
receiving error map information of the optical element;
wherein providing the pulsed laser irradiation is based at least partly on the error map information; and
adjusting the pulse power, the pulse pitch, and/or the laser beam diameter of the laser irradiation directed onto the first region and of the laser irradiation directed onto the second region according to a predetermined function of the error map information.

6. The method of claim 1, wherein the optical element for the EUV wavelength range comprises a multilayer system; wherein the multilayer system is configured to reflect light in the EUV range, between 10 and 20 nm.

7. The method of claim 1, wherein the directing the laser irradiation onto the optical element for the EUV wavelength range comprises directing the laser irradiation onto a backside of the optical element for the EUV wavelength range

8. The method of claim 6, wherein the laser irradiation directed onto the optical element is adapted to treat a portion of the optical element near the absorber layer of the optical element, a portion spaced from the absorber layer by 200 nm or less.

9. The method of claim 6, further comprising:
reducing the reflectivity of the multilayer system of light in the EUV range by 0% to 10%;
shifting the wavelength of maximum reflectivity by 0 nm to 1 nm; and/or
keeping an uncorrectable registration impact below 1 nm for an EUV reflectivity reduction of at least 6%.

10. The method of claim 1, wherein the optical element for the EUV wavelength range comprises a mask.

11. The method of claim 1, further comprising:
creating a black border on the optical element by reducing a reflectivity of the optical element in at least one region of the optical element onto which the laser irradiation is directed, wherein the region at least partly extends along a rim of the optical element.

12. The method of claim 1, wherein
a wavelength of the pulsed laser irradiation is between 400 and 1500 nm;
the repetition rate of the pulsed laser irradiation is between 1 kHz and 1 MHz; and/or
a laser pulse length of the pulsed laser irradiation is in the femtosecond range.

13. The method of claim 1, wherein the first pulse and the second pulse of the plurality of pulses are separated by a time of at least 10 ns.

14. The method of claim 1, wherein the pulses of the plurality of pulses are repeated at a frequency of 10 MHz to 1 GHz.

15. The method of claim 1, wherein at least one of the pulses comprises at least one sub-sequence comprising a plurality of sub-pulses;
wherein a first sub-pulse and a second sub-pulse of the plurality of sub-pulses are separated by a time between 1 ps and 100 ns; and/or
wherein the sub-pulses of the plurality of sub-pulses are repeated at a frequency of 1 GHz to 100 GHz.

16. The method of claim 1, wherein the first pulse comprises an intensity that is different from an intensity of the second pulse.

17. The method of claim 1, wherein the laser irradiation is directed onto a surface of the optical element for the EUV wavelength range with a laser beam diameter in the range between 1 μm to 100 μm; and/or
further comprising adjusting at least one parameter of the pulsed laser irradiation based at least in part on the dimensions of the optical element for the EUV wavelength range.

18. The method of claim 1, wherein the method is further adapted to provide an essentially small uncorrectable registration error over at least a part of the optical element.

19. An apparatus for treating an optical element for the extreme ultraviolet (EUV) wavelength range, wherein the apparatus comprises:
a laser source configured to provide a pulsed laser irradiation, wherein the pulsed laser irradiation comprises:
a plurality of pulse sequences, each pulse sequence comprising a plurality of pulses; wherein a first pulse and a second pulse of the plurality of pulses are separated by a time of 100 ns or less; and
means for directing the laser irradiation onto the optical element for the EUV wavelength range.

20. The apparatus of claim 19, further comprising a control means configured to control the apparatus to, preferably automatically, execute a method for treating the optical element, the method comprising:
controlling the laser source to provide the pulsed laser irradiation; and
controlling the means for directing the laser irradiation to direct the laser irradiation onto the optical element for the EUV wavelength range.
